(19) United States
(12) Patent Application Publication
(10) Pub. No.: US 2023/0077489 A1
(43) Pub. Date: Mar. 16, 2023

(54) 3D AND FLASH MEMORY DEVICE AND METHOD OF FABRICATING THE SAME

(71) Applicant: MACRONIX International Co., Ltd., Hsinchu (TW)

(72) Inventors: Min-Feng Hung, Hsing-Chu (TW); Pi-Shan Tseng, Hsing-Chu (TW)

(73) Assignee: MACRONIX International Co., Ltd., Hsinchu (TW)

(21) Appl. No.: 17/477,267

(22) Filed: Sep. 16, 2021

(51) Int. Cl. H01L 27/11582; H01L 27/11556

(52) U.S. Cl. CPC H01L 27/11582; H01L 27/11556

(57) ABSTRACT

A 3D AND flash memory device includes a gate stack structure, a plurality of channel pillars, a plurality of first conductive pillars and a plurality of second conductive pillars, a plurality of charge storage structures, and a plurality of isolation walls. The gate stack structure is located on a dielectric substrate and includes a plurality of gate layers and a plurality of insulating layers alternately stacked on each other. The channel pillars pass through the gate stack structure. The first conductive pillars and the second conductive pillars are located in the channel pillars and are electrically connected to the channel pillars. The charge storage structures are located between the gate layers and the channel pillar. The isolation walls are buried in the gate layers and cover the charge storage structures at outer sidewalls of the second conductive pillars.

### BACKGROUND

### Technical Field

The embodiment of the disclosure relates to a semiconductor device and a method of fabricating the same, and particularly, to a 3D AND flash memory device and a method of fabricating the same.

### Description of Related Art

Since a non-volatile memory has the advantage that stored data does not disappear at power-off, it becomes a widely used memory for a personal computer or other electronics equipment. Currently, the three-dimensional (3D) memory commonly used in the industry includes a NOR memory and a NAND memory. In addition, another type of 3D memory is an AND memory, which can be applied to a multi-dimensional memory array with high integration and high area utilization, and has an advantage of a fast operation speed. Therefore, the development of a 3D memory has gradually become the current trend.

### SUMMARY

The embodiment of the disclosure provides a 3D AND flash memory device and a method of fabricating the same, which can reduce gate induced drain leakage (GIDL).

According to an embodiment of the disclosure, a 3D AND flash memory device includes a gate stack structure, a plurality of channel pillars, a plurality of first conductive pillars and a plurality of second conductive pillars, a plurality of charge storage structures, and a plurality of isolation walls. The gate stack structure is located on a dielectric substrate and includes a plurality of gate layers and a plurality of insulating layers alternately stacked on each other. The channel pillars pass through the gate stack structure. The source pillars and the second conductive pillars are located in the channel pillars and are electrically connected to the channel pillars. The charge storage structures are located between the gate layers and the channel pillar. The isolation walls are buried in the gate layers and cover the charge storage structures at outer edges of the second conductive pillars.

According to an embodiment of the disclosure, a 3D AND flash memory device includes a stack structure, a plurality of channel pillars, a plurality of source pillars and a plurality of drain pillars, and a plurality of charge storage structures. The gate stack structure is located on a dielectric substrate and includes a plurality of gate layers and a plurality of insulating layers alternately stacked on each other. The channel pillars pass through the gate stack structure. The source pillars and the drain pillars are located in the channel pillars and are in contact with the channel pillars. The charge storage structures are located between the gate layers and the channel pillar. A sidewall of the gate layers is not in contact with a sidewall of a first part of the charge storage structures, and the sidewall of the first part of the charge storage structures covers around the channel pillars that are in contact with the drain pillars.

According to an embodiment of the disclosure, a method of fabricating a 3D AND flash memory device includes the following steps. A stack structure is formed on a dielectric substrate. The gate stack structure includes a plurality of sacrificial layers and a plurality of insulating layers alternately stacked on each other. A plurality of channel pillars extending through the gate stack structure are formed. A plurality of first conductive pillars and a plurality of second conductive pillars are formed in the channel pillars and are in contact with the channel pillars. The sacrificial layers are partially removed to form a plurality of horizontal openings, and unremoved portions of the sacrificial layers form a plurality of isolation walls, and the isolation walls have a curved profile. A plurality of gate layers are formed in the horizontal openings. A plurality of charge storage structures are formed between the gate layers and the channel pillar, and the isolation walls cover the charge storage structures at outer edges of the second conductive pillars.

Based on the above, in the embodiments of the disclosure, the isolation wall covers around the drain pillar, so that the gate layer does not overlap with the drain pillar, and gate induced drain leakage can be reduced.

### BRIEF DESCRIPTION OF THE DRAWINGS

FIG. 1A shows a circuit diagram of a 3D AND flash memory array according to some embodiments.

FIG. 1B shows a top view of a 3D AND flash memory array according to some embodiments.

FIG. 1C shows a partial simplified perspective view of a part of the memory array in FIG. 1B.

FIG. 1D and FIG. 1E show cross-sectional views taken along line I-I′ of FIG. 1C.

FIG. 1F shows a top view taken along line II-II′ of FIG. 1C, FIG. 1D, and FIG. 1E.

FIG. 1G is a schematic cross-sectional view taken along line V-V′ in FIG. 1F.

FIG. 2A to FIG. 2I are schematic cross-sectional views of a 3D AND flash memory device according to an embodiment of the disclosure. FIG. 2D, FIG. 2E, FIG. 2G, FIG. 2H, and FIG. 2I are cross-sectional views taken along line IV-IV′ of FIG. 3A to FIG. 3E.

FIG. 3A to FIG. 3E show top views taken along line III-III′ of FIG. 2D, FIG. 2E, FIG. 2G, FIG. 2H, and FIG. 2I.

FIG. 4A to FIG. 4D are top views of memory cells according to multiple embodiments of the disclosure.

FIG. 5A to FIG. 5C are top views of memory arrays according to multiple embodiments of the disclosure.

FIG. 6 is a cross-sectional view of a 3D AND flash memory device according to an embodiment of the disclosure.

### DESCRIPTION OF THE EMBODIMENTS

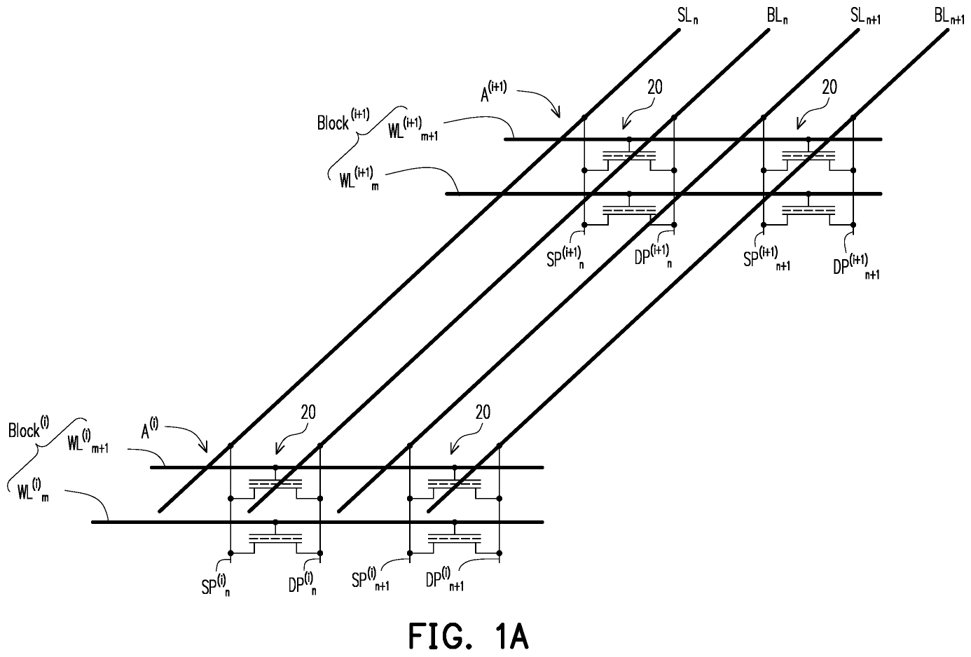

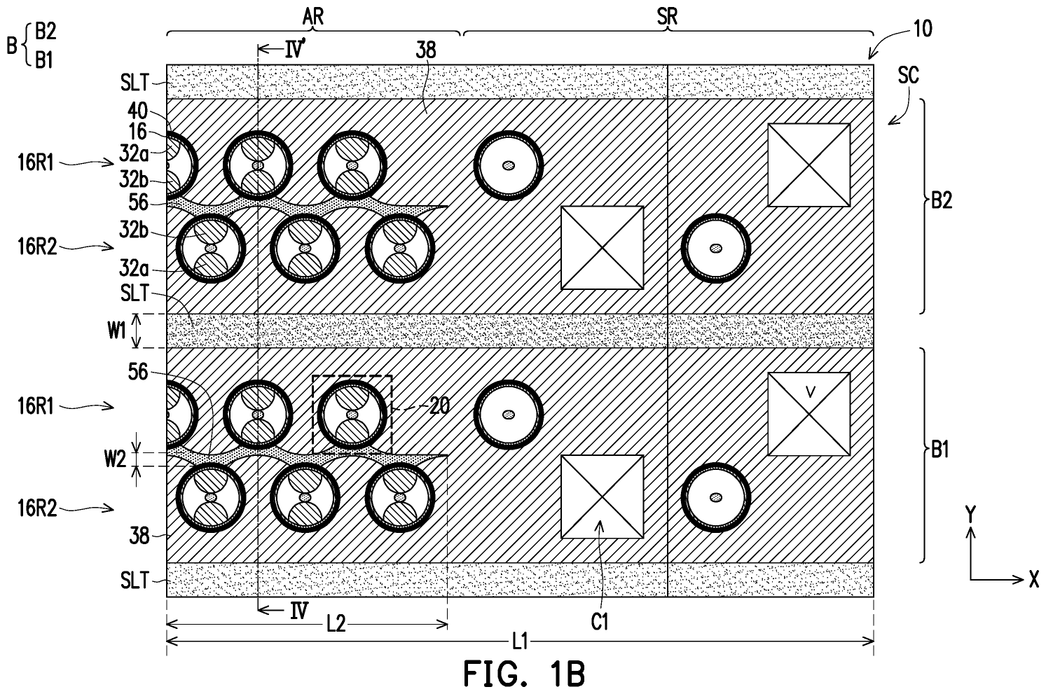

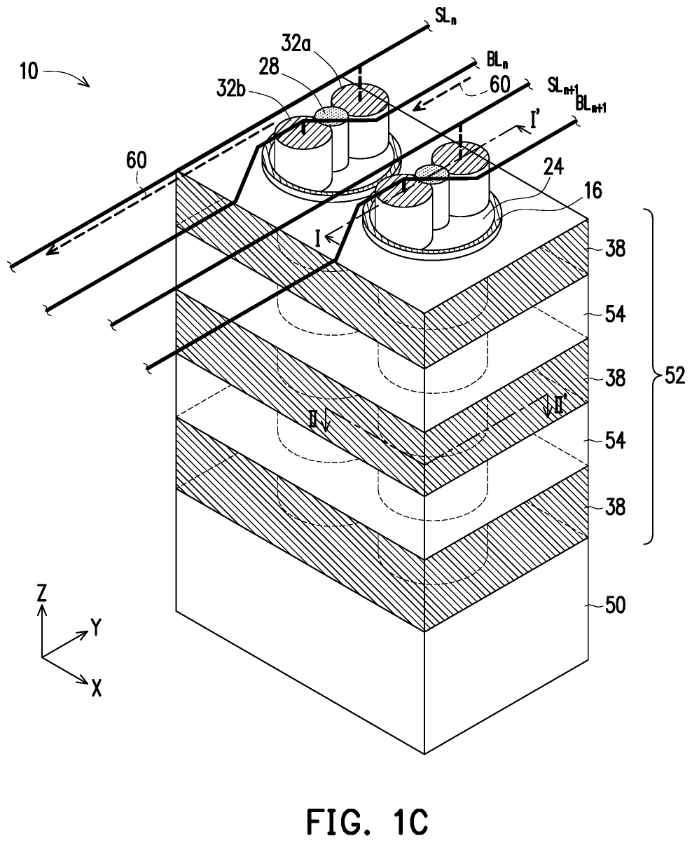

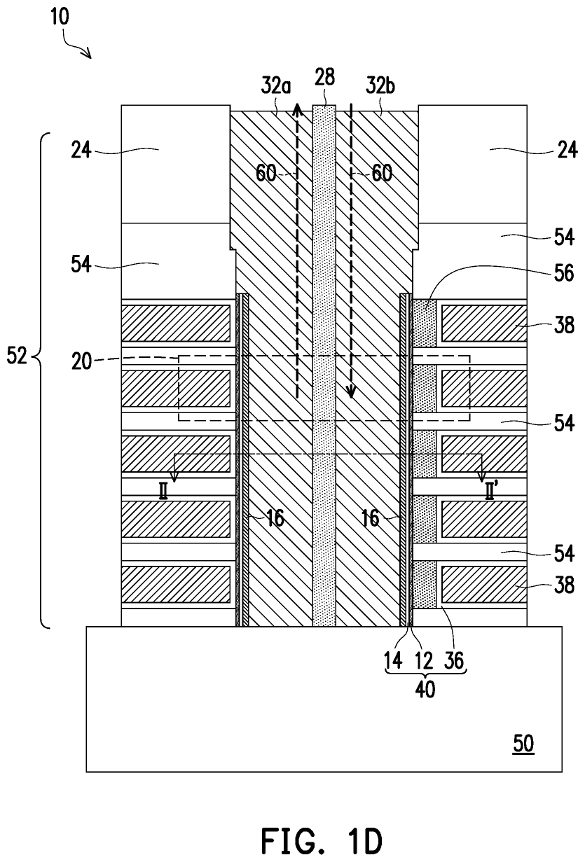

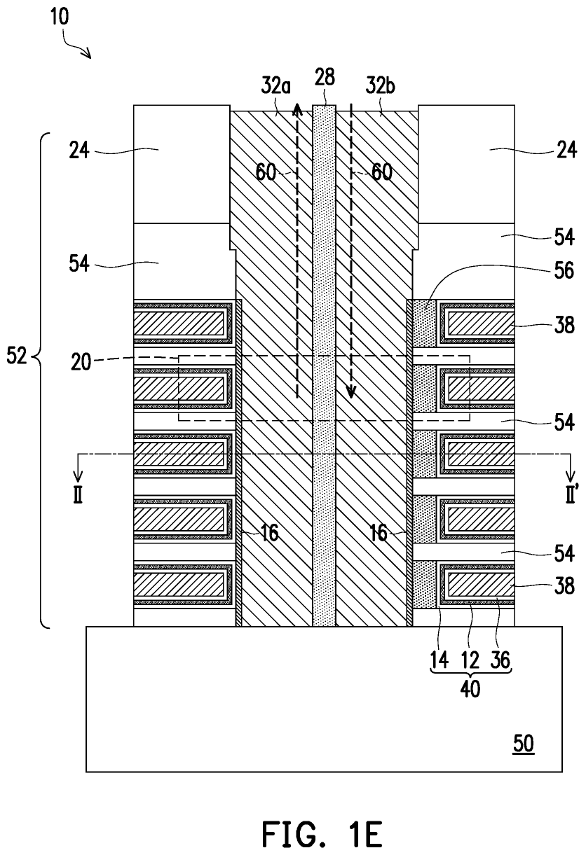

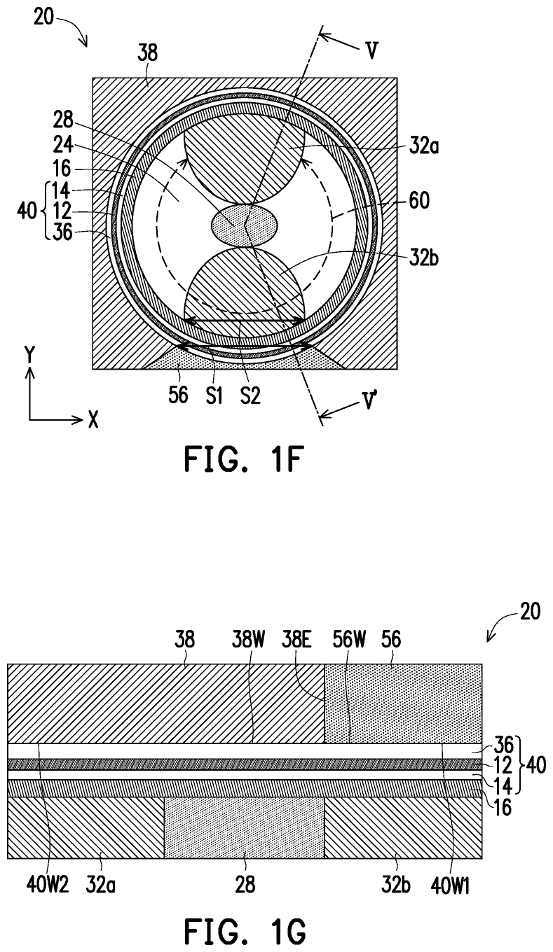

FIG. 1A shows a circuit diagram of a 3D AND flash memory array according to some embodiments. FIG. 1B shows a top view of a 3D AND flash memory array according to some embodiments. FIG. 1C shows a partial simplified perspective view of a part of the memory array in FIG. 1B. FIG. 1D and FIG. 1E show cross-sectional views taken along line I-I′ of FIG. 1C. FIG. 1F shows a top view taken along line II-II′ of FIG. 1C, FIG. 1D, and FIG. 1E. FIG. 1G is a schematic cross-sectional view taken along line V-V′ in FIG. 1F.

FIG. 1A shows a schematic view of two blocks BLOCK⁽ⁱ⁾ and BLOCK⁽ⁱ⁾ of a vertical AND memory array 10 arranged in rows and columns. The block BLOCK⁽ⁱ⁾ includes a memory array A⁽ⁱ⁾. A row (e.g., an (m+1)^{th} row) of the memory array A⁽ⁱ⁾ is a set of AND memory cells 20 having a common word line (e.g., WL⁽ⁱ⁾ₘ₊₁). The AND memory cells 20 of the memory array A⁽ⁱ⁾ in each row (e.g., the (m+1)^{th} row) correspond to a common word line (e.g., WL⁽ⁱ⁾ₘ₊₁) and are coupled to different source pillars (e.g., SP⁽ⁱ⁾ₙ and SP⁽ⁱ⁾ₙ₊₁) and drain pillars (e.g., DP⁽ⁱ⁾ₙ and DP⁽ⁱ⁾ₙ₊₁), so that the AND memory cells 20 are logically arranged in a row along the common word line (e.g., WL⁽ⁱ⁾ₘ₊₁).

A column (e.g., an n^{th} column) of the memory array A⁽ⁱ⁾ is a set of AND memory cells 20 having a common source pillar (e.g., SP⁽ⁱ⁾ₙ) and a common drain pillar (e.g., DP⁽ⁱ⁾ₙ). The AND memory cells 20 of the memory array AC⁽ⁱ⁾ in each column (e.g., the n^{th} column) correspond to different word lines (e.g., WL⁽ⁱ⁾ₘ₊₁ and WL⁽ⁱ⁾ₘ) and are coupled to a common source pillar (e.g., SP⁽ⁱ⁾ₙ) and a common drain pillar (e.g., DP⁽ⁱ⁾ₙ). Hence, the AND memory cells 20 of the memory array A⁽ⁱ⁾ are logically arranged in a column along the common source pillar (e.g., SP⁽ⁱ⁾ₙ) and the common drain pillar (e.g., DP⁽ⁱ⁾ₙ). In the physical layout, according to the fabrication method as applied, the columns or rows may be twisted and arranged in a honeycomb pattern or other patterns for high density or other reasons.

In FIG. 1A, in the block BLOCK⁽ⁱ⁾, the AND memory cells 20 in the n^{th} column of the memory array A⁽ⁱ⁾ share a common source pillar (e.g., SP⁽ⁱ⁾ₙ) and a common drain pillar (e.g., DP⁽ⁱ⁾ₙ). The AND memory cells 20 in an (n+1)^{th} column share a common source pillar (e.g., SP⁽ⁱ⁾ₙ₊₁) and a common drain pillar (e.g., DP⁽ⁱ⁾ₙ₊₁). The common source pillar (e.g., SP⁽ⁱ⁾ₙ) is coupled to a common source line (e.g., SLₙ) and the common drain pillar (e.g., DP⁽ⁱ⁾ₙ₊₁) is coupled to a common bit line (e.g., BLₙ). The common source pillar (e.g., SP⁽ⁱ⁾ₙ₊₁) is coupled to a common source line (e.g., SLₙ₊₁) and the common drain pillar (e.g., DP⁽ⁱ⁾ₙ₊₁) is coupled to a common bit line (e.g., BLₙ₊₁).

Likewise, the block BLOCK⁽ⁱ⁺¹⁾ includes a memory array A⁽ⁱ⁺¹⁾, which is similar to the memory array A⁽ⁱ⁾ in the block BLOCK⁽ⁱ⁾. A row (e.g., an (m+1)^{th} row) of the memory array A⁽ⁱ⁺¹⁾ is a set of AND memory cells 20 having a common word line (e.g., WL⁽ⁱ⁺¹⁾ₘ₊₁). The AND memory cells 20 of the memory array A⁽ⁱ⁺¹⁾ in each row (e.g., the (m+1)^{th} row) correspond to a common word line (e.g., WL⁽ⁱ⁺¹⁾ₘ₊₁) and are coupled to different source pillars (e.g., SP⁽ⁱ⁺¹⁾ₙ and SP⁽ⁱ⁺¹⁾ₙ₊₁) and drain pillars (e.g., DP⁽ⁱ⁺¹⁾ₙ₊₁ and DP⁽ⁱ⁺¹⁾ₙ₊₁). A column (e.g., an n^{th} column) of the memory array A⁽ⁱ⁺¹⁾ is a set of AND memory cells 20 having a common source pillar (e.g., SP⁽ⁱ⁺¹⁾ₙ) and a common drain pillar (e.g., DP⁽ⁱ⁺¹⁾ₙ). The AND memory cells 20 of the memory array A⁽ⁱ⁺¹⁾ in each column (e.g., the n^{th} column) correspond to different word lines (e.g., WL⁽ⁱ⁺¹⁾ₘ₊₁ and WL⁽ⁱ⁺¹⁾ₘ) and are coupled to a common source pillar (e.g., SP⁽ⁱ⁺¹⁾ₙ) and a common drain pillar (e.g., DP⁽ⁱ⁺¹⁾ₙ). Hence, the AND memory cells 20 of the memory array A⁽ⁱ⁺¹⁾ are logically arranged in a column along the common source pillar (e.g., SP⁽ⁱ⁺¹⁾ₙ) and the common drain pillar (e.g., DP⁽ⁱ⁺¹⁾ₙ).

The block BLOCK⁽ⁱ⁺¹⁾ and the block BLOCK⁽ⁱ⁾ share source lines (e.g., SLₙ and SLₙ₊₁) and bit lines (e.g., BLₙ and BLₙ₊₁). Therefore, the source line SLₙ and the bit line BLₙ are coupled to the n^{th} column of AND memory cells 20 in the AND memory array A⁽ⁱ⁾ of the block BLOCK⁽ⁱ⁾, and are coupled to the n^{th} column of AND memory cells 20 in the AND memory array A⁽ⁱ⁺¹⁾ of the block BLOCK⁽ⁱ⁺¹⁾. Similarly, the source line SLₙ₊₁ and the bit line BLₙ₊₁ are coupled to the (n+1)^{th} column of AND memory cells 20 in the AND memory array A⁽ⁱ⁾ of the block BLOCK⁽ⁱ⁾, and are coupled to the (n+1)^{th} column of AND memory cells 20 in the AND memory array A⁽ⁱ⁺¹⁾ of the block BLOCK⁽ⁱ⁺¹⁾.

Referring to FIG. 1B to FIG. 1D, the memory array 10 may include multiple blocks, such as a block B1 and a block B2. A slit SLT separates a gate stack structure 52 of the two adjacent blocks B1 and B2. The slit SLT is an insulating material. The insulating material may include an organic insulating material, an inorganic insulating material, or a combination thereof. The blocks B1 and B2 may each include a gate stack structure 52, a plurality of channel pillars 16, a plurality of first conductive pillars (also referred to as source pillars) 32a, a plurality of second conductive pillars (also referred to as drain pillars) 32b, and a plurality of charge storage structures 40, which are disposed on a dielectric substrate 50.

Referring to FIG. 1D, the memory array 10 may be disposed over an interconnect structure of a semiconductor die, for example, being disposed on one or more active devices (e.g., transistors) formed on a semiconductor substrate. Therefore, the dielectric substrate 50 is, for example, a dielectric layer (e.g., a silicon oxide layer) over a metal interconnect structure formed on a silicon substrate. The dielectric substrate 50 may include an array region AR and a staircase region SR (shown in FIG. 1B).

Referring to FIG. 1B and FIG. 1C, a gate stack structure 52 is formed on the dielectric substrate 50 in the array region AR and the staircase region SR. The gate stack structure 52 includes a plurality of gate layers (also referred to as word lines) 38 and a plurality of insulating layer 54 vertically stacked on the surface of the dielectric substrate 50 (shown in FIG. 1D and FIG. 1E). In the Z direction, the gate layers 38 are electrically isolated from each other by the insulating layer 54 disposed therebetween. The gate layer 38 extends in a direction parallel to the surface of the dielectric substrate 50 (shown in FIG. 1D). As shown in FIG. 1B, the gate layers 38 in the staircase region SR may have a staircase structure SC. Therefore, a lower gate layer 38 is longer than an upper gate layer 38, and the end of the lower gate layer 38 extends laterally beyond the end of the upper gate layer 38. As shown in FIG. 1B, a contact C1 for connecting the gate layer 38 may land on the end of the gate layer 38 to connect the gate layers 38 respectively to conductive lines.

Referring to FIG. 1B to FIG. 1E, the memory array 10 further includes a plurality of channel pillars 16. The channel pillar 16 continuously extends through the gate stack structure 52 in the array region AR. In some embodiments, the channel pillar 16 may have a ring-shaped profile in a top view (shown in FIG. 1B). The material of the channel pillar 16 may be semiconductor such as undoped polysilicon.

Referring to FIG. 1C to FIG. 1E, the memory array 10 further includes an insulating filling layer 24, an insulating pillar 28, a plurality of first conductive pillars 32a, and a plurality of second conductive pillars 32b. In this example, the first conductive pillars 32a act as source pillars. The second conductive pillars 32b act as drain pillars. The first and second conductive pillars 32a and 32b and the insulating pillar 28 are disposed in the channel pillar 16 and each extend in a direction (i.e., the Z direction) perpendicular to the gate layer 38. The first and second conductive pillars 32a and 32b are separated from each other by the insulating filling layer 24 and the insulating pillar 28. The insulating filling layer 24 is in the space not occupied by the first and second conductive pillars 32a and 32b, and the insulating pillar 28 surrounded by the channel pillar 16, which extends in the direction (i.e., the Z direction) perpendicular to the gate layer 38. The first and second conductive pillars 32a and 32b electrically connect to the channel pillar 16. The first and second conductive pillars 32a and 32b comprises doped polysilicon or metal materials. The insulating pillar 28 is, for example, silicon nitride.

Referring to FIG. 1D and FIG. 1E, at least a portion of a charge storage structure 40 is disposed between the channel pillar 16 and the gate layers 38. The charge storage structure 40 may include a tunneling layer (or referred to as a bandgap engineered tunneling oxide layer) 14, a charge storage layer 12, and a blocking layer 36. The charge storage layer 12 is located between the tunneling layer 14 and the blocking layer 36. In some embodiments, the tunneling layer 14, and the blocking layer 36 comprise silicon oxide or other materials including oxide. The charge storage layer 12 comprises silicon nitride or other materials capable of trapping charges. In some embodiments as shown in FIG. 1D, a part (the tunneling layer 14 and the charge storage layer 12) of the charge storage structure 40 continuously extends in a direction (i.e., the Z direction) perpendicular to the gate layer 38, and the other part (the blocking layer 36) of the charge storage structure 40 surrounds the gate layer 38. In other embodiments as shown in FIG. 1E, the charge storage structure 40 (the tunneling layer 14, the charge storage layer 12, and the blocking layer 36) surrounds the gate layer 38.

Referring to FIG. 1F, the charge storage structure 40, the channel pillar 16, the source pillar 32a, and the drain pillar 32b are surrounded by the gate layer 38 and a memory cell 20 is defined. According to different operation methods, a 1-bit operation or a 2-bit operation may be performed on the memory cell 20. For example, when a voltage is applied to the source pillar 32a and the drain pillar 32b, since the source pillar 32a and the drain pillar 32b are connected to the channel pillar 16, electrons may be transferred along the channel pillar 16 and stored in the entire charge storage structure 40. Accordingly, a 1-bit operation may be performed on the memory cell 20. In addition, for an operation involving Fowler-Nordheim tunneling, electrons or holes may be trapped in the charge storage structure 40 between the source pillar 32a and the drain pillar 32b. For an operation involving source side injection, channel-hot-electron injection, or band-to-band tunneling hot carrier injection, electrons or holes may be locally trapped in the charge storage structure 40 adjacent to one of the source pillar 32a and the drain pillar 32b. Accordingly, a single level cell (SLC, 1 bit) or multi-level cell (MLC, greater than or equal to 2 bits) operation may be performed on the memory cell 20.

During operation, a voltage is applied to a selected word line (gate layer) 38; for example, when a voltage higher than a corresponding threshold voltage (Vₜₕ) of the corresponding memory cell 20 is applied, a channel region of the channel pillar 16 intersecting the selected word line 38 is turned on to allow a current to enter the drain pillar 32b from the bit line BLₙ or BLₙ₊₁ in FIG. 1C), flow to the source pillar 32a via the turned-on channel region (e.g., in a direction indicated by arrow 60), and finally flow to the source line SLₙ or SLₙ₊₁ (shown in FIG. 1C).

However, if the gate layer 38 surrounds and covers the drain pillar 32b, it is likely to cause gate induced drain leakage. In the embodiment of the disclosure, an isolation wall 56 is buried in the gate layer 38, so that the gate layer 38 does not cover around the drain pillar 32b, and therefore, it is possible to reduce or avoid gate induced drain leakage.

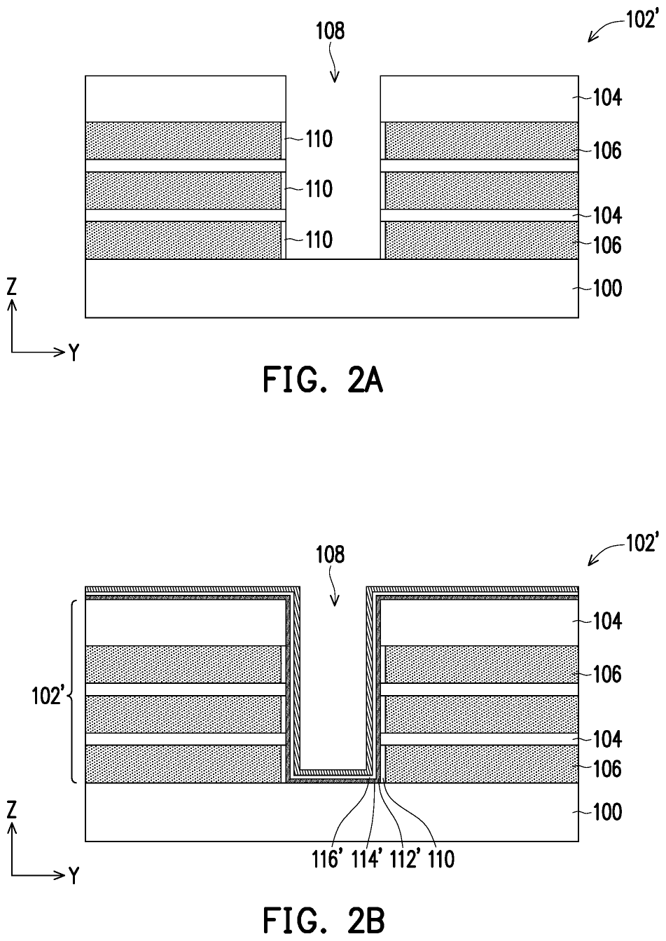

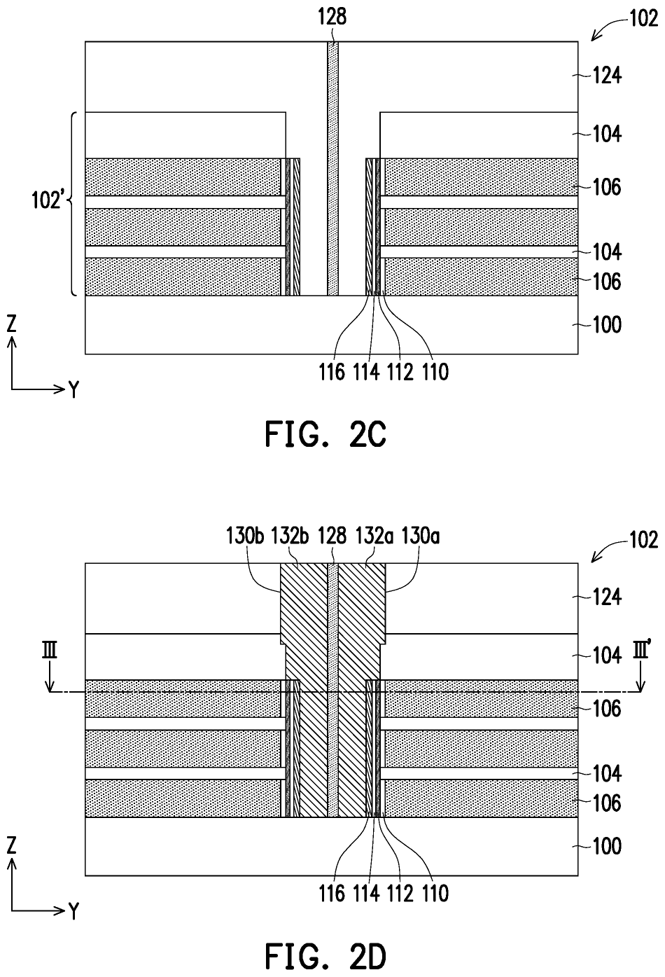

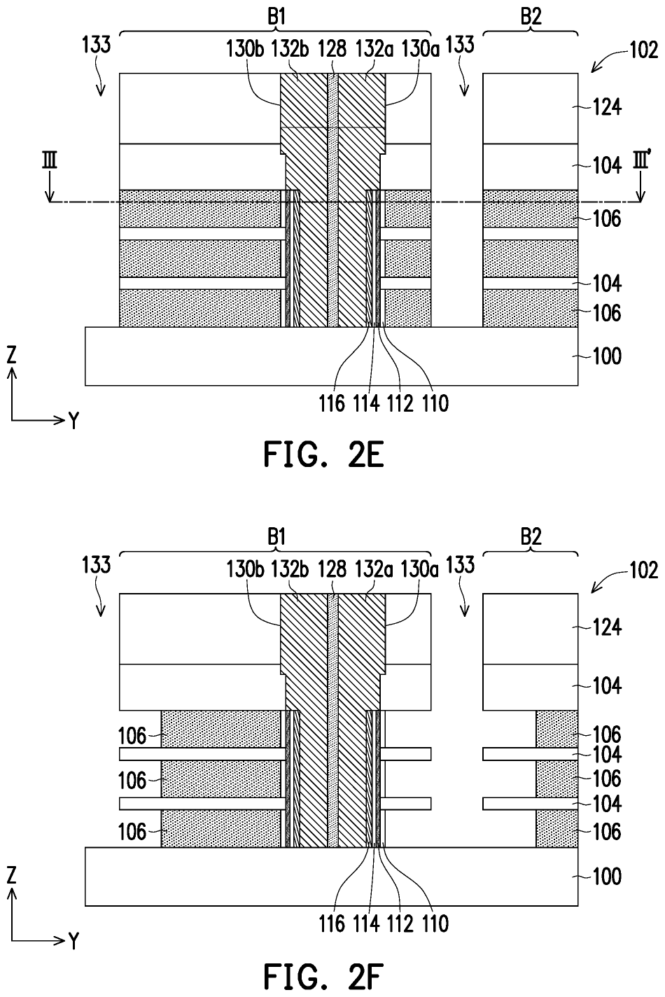

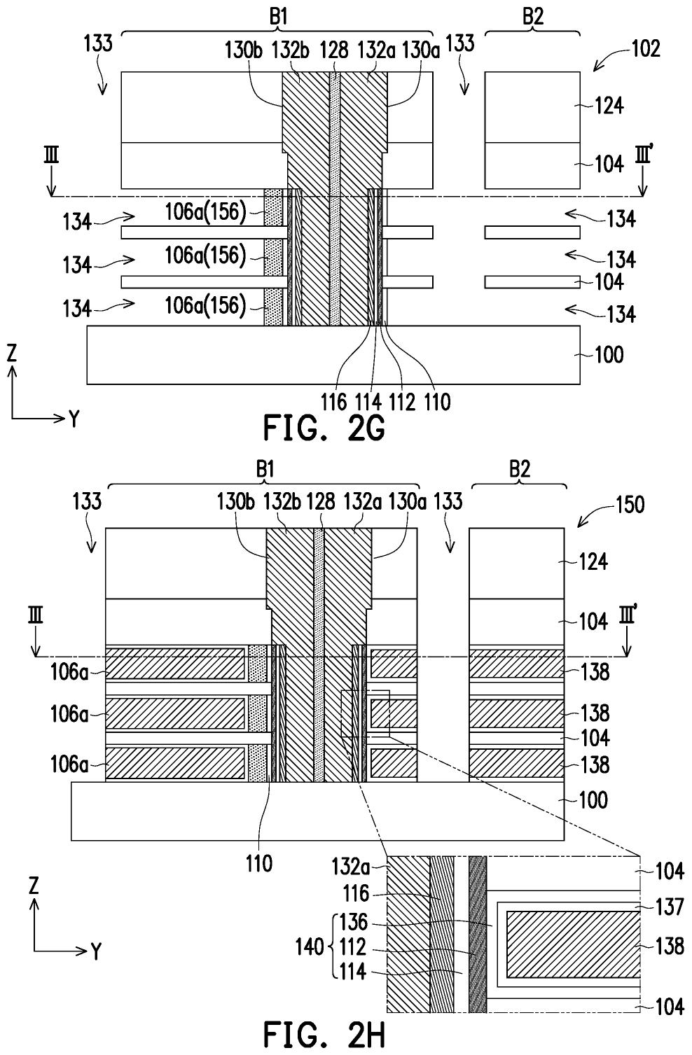

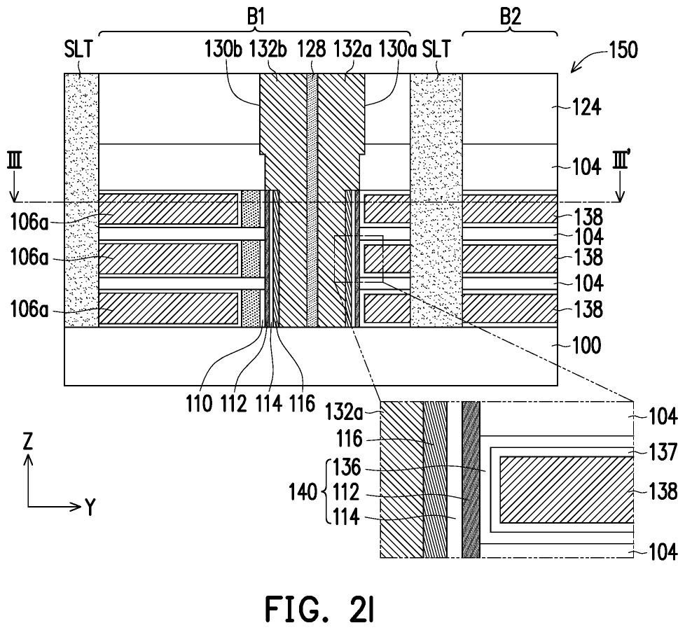

Referring to FIG. 1B, the gate layer 38 is formed by performing a gate replacement process on a sacrificial layer (similar to the sacrificial layer 106 shown in FIG. 2G) stacked between the insulating layers 54. In the disclosure, parts of the sacrificial layers are left to form the isolation walls 56 (similar to the isolation walls 156 shown in FIG. 2G). Referring back to FIG. 1B, each isolation wall 56 extends in the X direction and separates the channel pillars 16 in each block B into first row channel pillars 16R1 and second row channel pillars 16R2. The isolation wall 56 and the slit SLT both extend in the X direction. The slit SLT extends continuously. The isolation wall 56 may extend continuously or extend discontinuously. A length L1 of the slit SLT in the X direction is greater than or equal to a length L2 of the isolation wall 56 in the X direction. Furthermore, the isolation wall 56 and the slit SLT have different shapes. In a top view, the slit SLT is substantially rectangular, and the isolation wall 56 has a curved shape, as shown in FIG. 1B.

FIG. 1G is a schematic cross-sectional view taken along line V-V′ in FIG. 1F. Referring to FIG. 1F and FIG. 1G, the isolation wall 56 is buried in the gate layers 38, and covers and contacts the charge storage structures 40 at the outer sidewalls of the drain pillars 32b, as shown in FIG. 1F. A contact range between the isolation wall 56 and the charge storage structure 40 may be controlled through an etching process.

In this embodiment (as shown FIG. 1G), a sidewall 56W of the isolation wall 56 is in contact with a sidewall 40W1 of a part of the charge storage structure 40. As illustrated in FIG. 1F, the part of the charge storage structure 40 contacts the isolation wall 56 and covers around a portion of the channel pillar 16. The portion of the channel pillar 16 is in contact with the drain pillar 32b. As shown in FIG. 1G, an edge 38 E of the gate layer 38 does not extend over the sidewall 40W1 of the part of the charge storage structure 40 and does not overlap the drain pillar 32b. A sidewall 38W of the gate layer 38 is not in contact with the sidewall 40W1 of the part of the charge storage structure 40. There is no overlapping between the gate layer 38 and the drain pillar 32b. Hence, an electric field between the gate layer 38 and the drain pillar 32b is reduced. The leakage current between the portion of the channel pillar 16 and the drain pillar 32b could be prevented.

In an embodiment, as shown in FIG. 1F, each of the charge storage structure 40 and the channel pillar 16 has a first chord length S1 and a second chord length S2, respectively. The first chord length S1 is a chord length of an arc surface of each charge storage structure 40 that is in contact with the adjacent isolation wall 56. The second chord length S2 is a chord length of an arc surface of the channel pillar 16 that is in contact with the adjacent drain pillar 32b. In this embodiment, the first chord length S1 is greater than or equal to the second chord length S2. The first chord length S1 is greater than or equal to the second chord length S2, so that the gate layer 38 and the drain pillar 32b do not overlap (as shown in FIG. 1G) to prevent gate induced drain leakage.

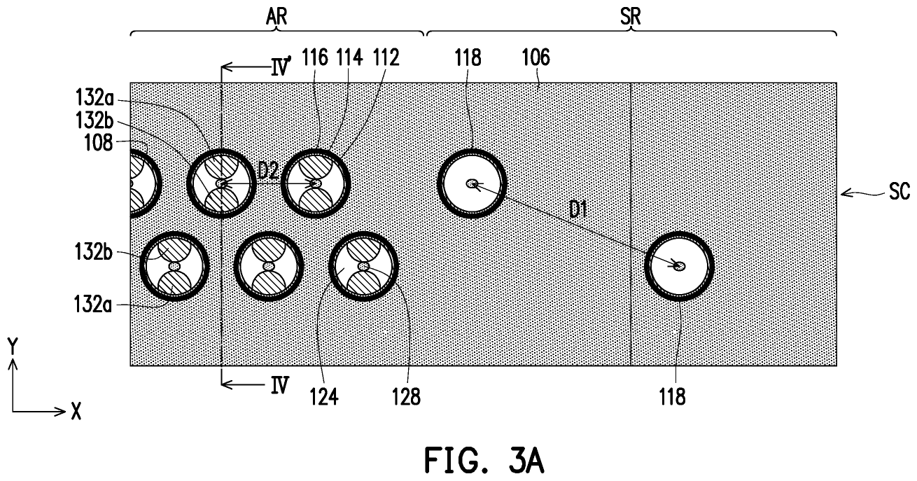

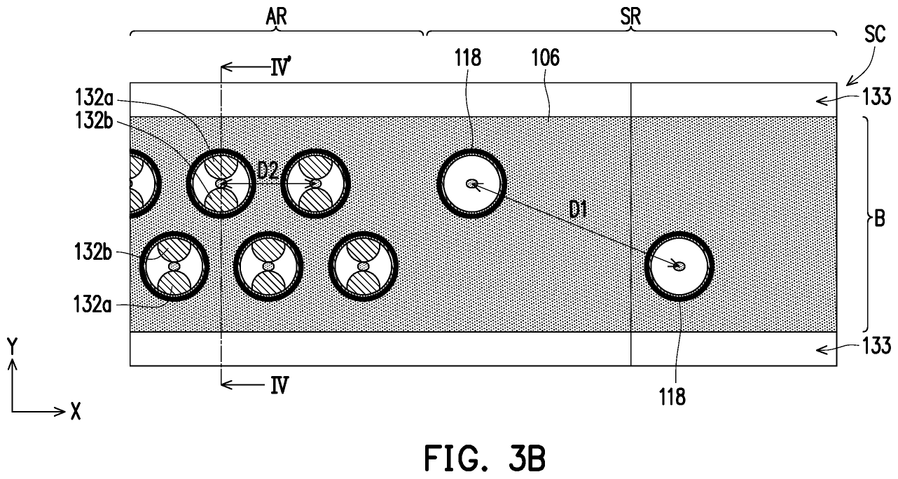

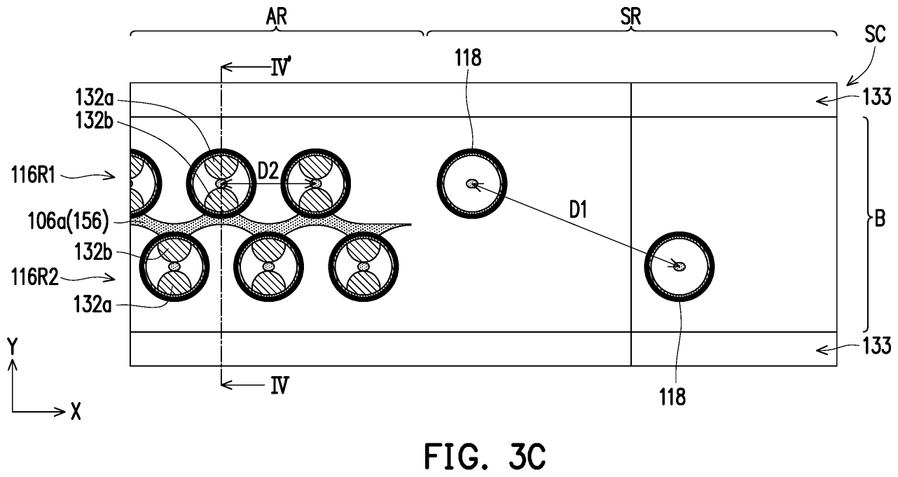

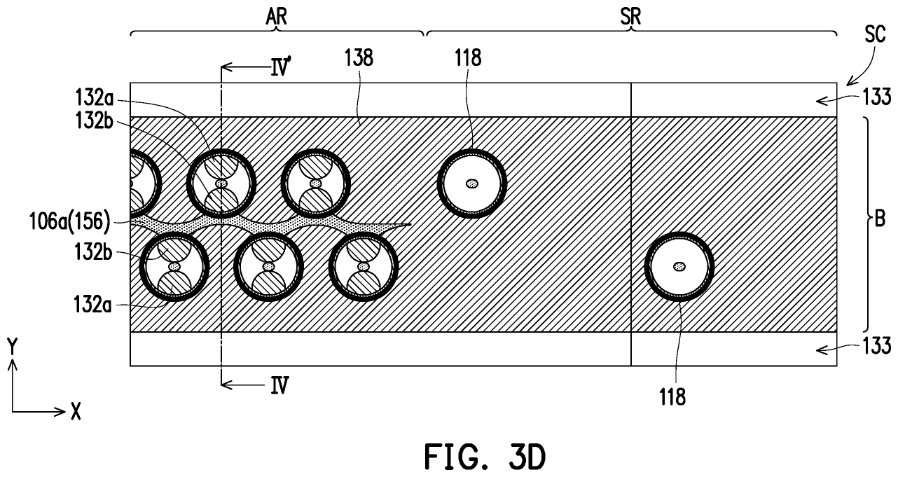

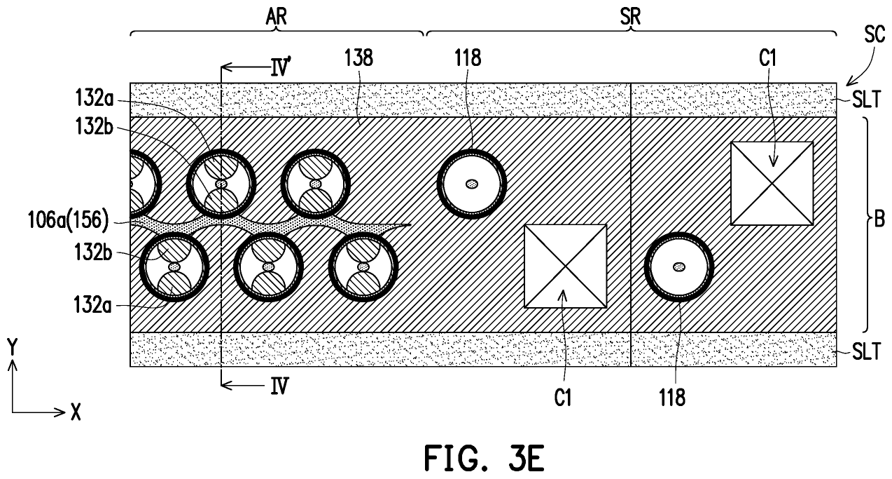

The isolation wall 56 and the slit SLT are formed by different methods, which will be described in detail below with reference to FIG. 2A to FIG. 2I and FIG. 3A to FIG. 3E. FIG. 2A to FIG. 2I are schematic cross-sectional views of a 3D AND flash memory device according to an embodiment of the disclosure. FIG. 2D, FIG. 2E, FIG. 2G, FIG. 2H, and FIG. 2I are cross-sectional views taken along line IV-IV′ of FIG. 3A to FIG. 3E. FIG. 3A to FIG. 3E show top views taken along line III-III′ of FIG. 2D, FIG. 2E, FIG. 2G, FIG. 2H, and FIG. 2I.

Referring to FIG. 2A, a dielectric substrate 100 is provided. The dielectric substrate 100 is, for example, a dielectric layer (e.g., a silicon oxide layer) having a metal interconnect structure formed on a silicon substrate. The dielectric substrate 100 includes an array region AR and a staircase region SR. A stack structure 102′ is formed on the dielectric substrate 100 in the array region AR and the staircase region SR. The stack structure 102′ may also be referred to as an insulating stack structure 102′. In this embodiment, the stack structure 102′ is composed of insulating layers 104 and sacrificial layers 106 that are sequentially alternately stacked on the dielectric substrate 100. In other embodiments, insulating layers 104 and sacrificial layers 106 are alternately stacked in a reverse sequence on the dielectric substrate 100. In addition, in this embodiment, the uppermost layer of the stack structure 102′ is the insulating layer 104. The insulating layer 104 is, for example, a silicon oxide layer. The sacrificial layer 106 is, for example, a silicon nitride layer. In this embodiment, the stack structure 102′ has three pairs of insulating layers 104 and sacrificial layers 106, but the disclosure is not limited thereto. In other embodiments, more pairs of insulating layers 104 and sacrificial layers 106 may be formed according to the actual requirements.

The stack structure 102′ is patterned to form a staircase structure SC in the staircase region SR (as shown in FIG. 3A).

Next, referring to FIG. 2A and FIG. 3A, a plurality of openings 108 are formed in the stack structure 102′ in the array region AR. However, only one opening 108 is shown in FIG. 2A. In this embodiment, the bottom surface of the opening 108 exposes the dielectric substrate 100, but the disclosure is not limited thereto. In other embodiments, when the lowermost layer of the stack structure 102′ is the insulating layer 104, the bottom of the opening 108 may be located in the lowermost insulating layer 104; namely, the bottom of the opening 108 may expose the lowermost insulating layer 104 without exposing the dielectric substrate 100. Alternatively, in other embodiments, the bottom of the opening 108 may further extend into the dielectric substrate 100. In this embodiment, in a top view, the opening 108 has a circular profile, but the disclosure is not limited thereto. In other embodiments, the opening 108 may have a profile of other shapes such as a polygonal shape (not shown). Afterwards, a thermal oxidation process is performed to oxidize the surface of the sidewall of the sacrificial layer 106 exposed by the opening 108 to form a protection layer 110 (e.g. an oxide layer).

Referring to FIG. 2B, a storage material layer 112′, a tunneling material layer 114′, and a channel material layer 116′ are formed on the stack structure 102′ and in the opening 108. The storage material layer 112′ is, for example, a silicon nitride layer. The tunneling material layer 114′ is, for example, a silicon oxide layer. The material of the channel material layer 116′ may be a semiconductor material such as undoped polysilicon.

Referring to FIG. 2C, an etch-back process is performed to partially remove the storage material layer 112′, the tunneling material layer 114′, and the channel material layer 116′ to form a charge storage layer 112, a tunneling layer 114, and a channel pillar 116. The charge storage layer 112, the tunneling layer 114, and the channel pillar 116 cover at least a portion of the sidewall of the opening 108 and expose the bottom of the opening 108. The charge storage layer 112, the tunneling layer 114, and the channel pillar 116 may extend through the stack structure 102′. In a top view, the channel pillar 116 has, for example, a ring shape and may be continuous in its extending direction (e.g., in a direction perpendicular to the dielectric substrate 100). In other words, the channel pillar 116 is integral in its extending direction and is not divided into multiple disconnected parts. In some embodiments, the channel pillar 116 may have a circular shape in a top view, but the disclosure is not limited thereto. In other embodiments, the channel pillar 116 may also have a profile of other shapes (e.g., a polygon) in a top view.

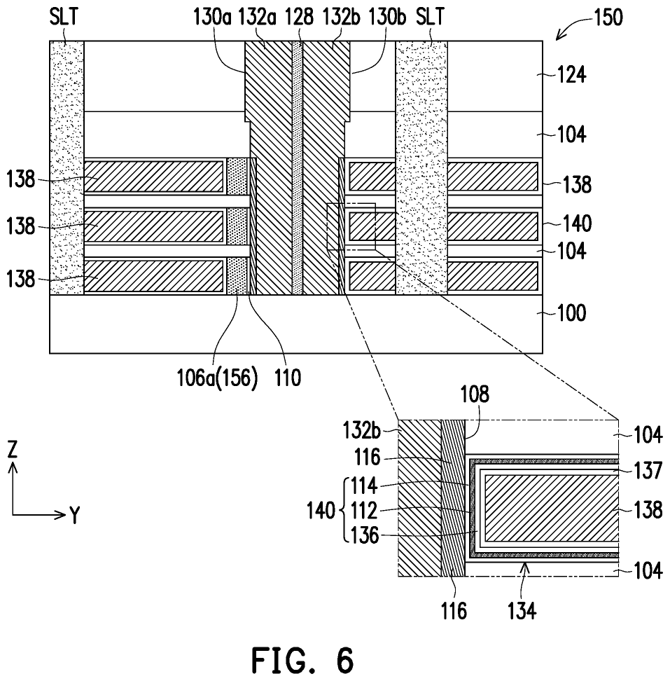

In this embodiment, the charge storage layer 112 and the tunneling layer 114 are formed in the opening 108. In another embodiment, the charge storage layer 112 and the tunneling layer 114 are formed in a horizontal opening 134 in the gate replacement process, as shown in FIG. 6, which will be described in detail later.

Referring to FIG. 2B and FIG. 2C, an insulating filling layer 124 is formed on the stack structure 102′ and in the opening 108. The stack structure 102′ and the insulating filling layer 124 on the stack structure 102′ may be collectively referred to as a stack structure 102. The insulating filling layer 124 is located on the stack structure 102′, it may also be referred to as an insulating cap layer. The material of the insulating filling layer 124 is, for example, silicon oxide. During filling of the insulating filling layer 124 in the opening 108, when the opening 108 is not completely filled and a hole is left at the center of the opening 108, an insulating material different from the material of the insulating filling layer 124 is filled to completely seal the opening 108. After the insulating material is etched back to the surface of the insulating filling layer 124 through a dry etching or wet etching process, the insulating material remaining at the center of the opening 108 forms an insulating pillar 128. The material of the insulating pillar 128 is different from the material of the insulating filling layer 124 and may be, for example, silicon nitride.

Referring to FIG. 2D, a patterning process is performed to form holes 130a and 130b in the insulating filling layer 124. The holes 130a and 130b extend from the top surface of the insulating filling layer 124 to the dielectric substrate 100. The shapes of the hole patterns defined in the patterning process may be tangent to the shape of the insulating pillar 128. The shapes of the hole patterns defined in the patterning process may exceed the shape of the insulating pillar 128. Since the etching rate of the insulating pillar 128 is lower than the etching rate of the insulating filling layer 124, the insulating pillar 128 is hardly damaged by etching and remains.

Referring to FIG. 3A, in some embodiments, dummy pillars 118 are further formed in the staircase region SR. The dummy pillars 118 may serve as support pillars in the subsequent gate replacement process. The dummy pillars 118 may be formed at the same time when the charge storage layer 112, the tunneling layer 114, the channel pillar 116, the insulating filling layer 124, and the insulating pillar 128 are formed. The dummy pillars 118 may also be formed separately. The number of the dummy pillars 118 may be determined according to the requirements. In some embodiments, the dummy pillars 118 in the staircase region SR are staggered with each other, and a distance D1 between the dummy pillars 118 in the staircase region SR is greater than or equal to a distance D2 between the channel pillars 116, and a density of the dummy pillars 118 is lower than a density of the channel pillars 116 in the array region AR.

Referring to FIG. 2D and FIG. 3A, first and second conductive pillars 132a are formed in the holes 130a and 130b. The first conductive pillars 132a and second conductive pillars 132b may respectively serve as a source pillar and a drain pillar and are respectively electrically connected to the channel pillar 116. The first and second conductive pillars 132a may be formed by forming a conductive layer on the insulating filling layer 124 and in the holes 130a and 130b, and then performing an etching-back process. The first and second conductive pillars 132a are, for example, doped polysilicon. In this embodiment, the second conductive pillars (drain pillars) 132b in two adjacent rows are adjacent to each other, and the first conductive pillars (source pillars) 132a in two adjacent rows are away from each other. The second conductive pillars (drain pillars) 132b, are arranged at a position farthest away from a subsequently formed slit trench 133 (as shown in FIG. 3E), which helps to cover a remaining sacrificial layer 106a (i.e., the isolation wall 156) around the second conductive pillar 132b.

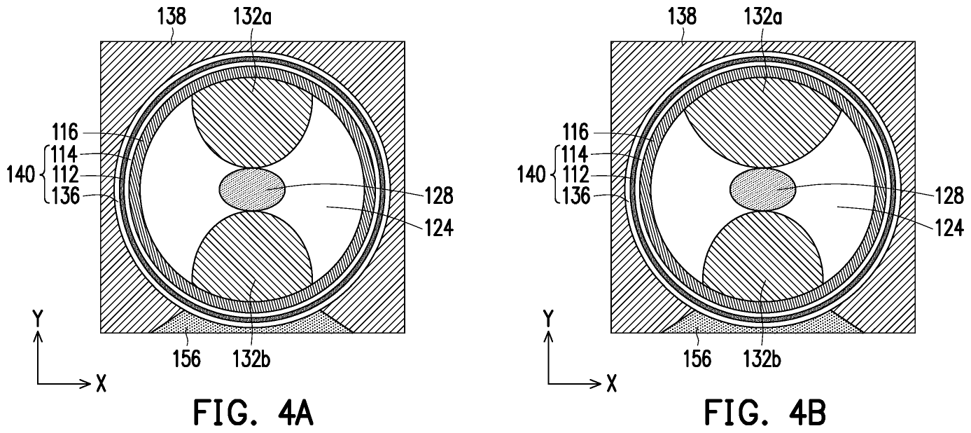

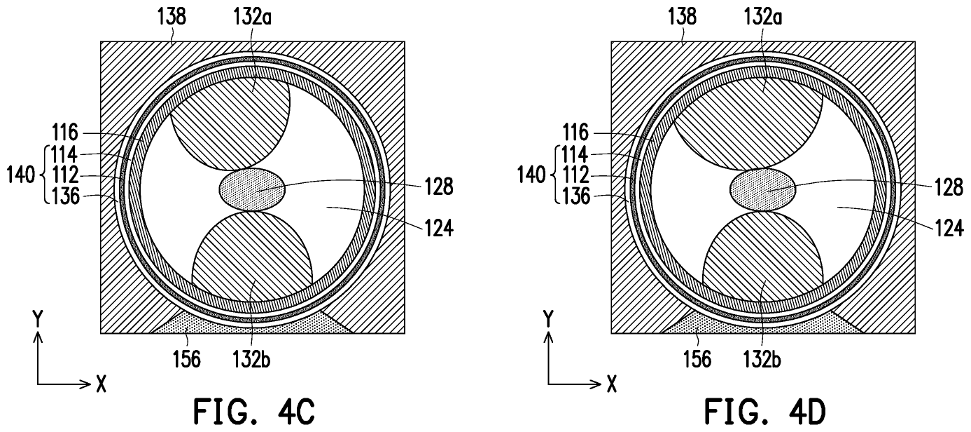

The radial dimensions of the first and second conductive pillars 132a may be the same (as shown in FIG. 4A and FIG. 4C) or different (as shown in FIG. 4B and FIG. 4D). In some embodiments, the radial dimension of the first conductive pillar 132a, which serves as the source pillar, may be greater than or equal to the radial dimension of the second conductive pillar 132b, which serves as the drain pillar (as shown in FIG. 4B and FIG. 4D). The first and second conductive pillars 132a may be symmetrically disposed with the center line of the channel pillar 116 as the symmetry axis and disposed along the Y direction (as shown in FIG. 4A and FIG. 4B). The first and second conductive pillars 132a may be disposed asymmetrically with the center line of the channel pillar 116 as the symmetry axis; that is, the conductive pillar 132a may shift with respect to the conductive pillar 132b (as shown in FIG. 4C and FIG. 4D).

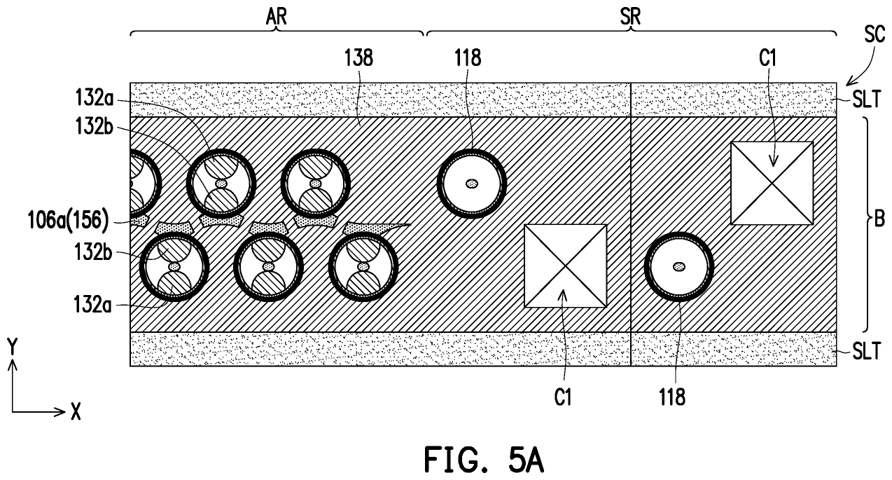

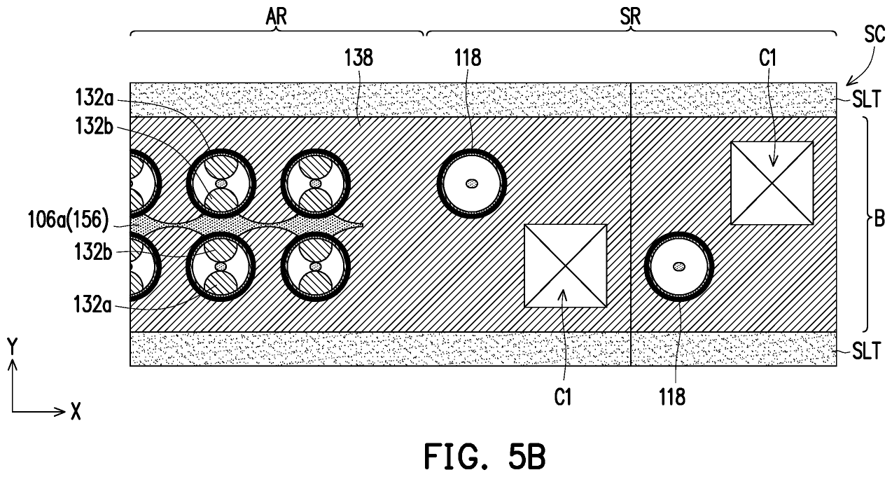

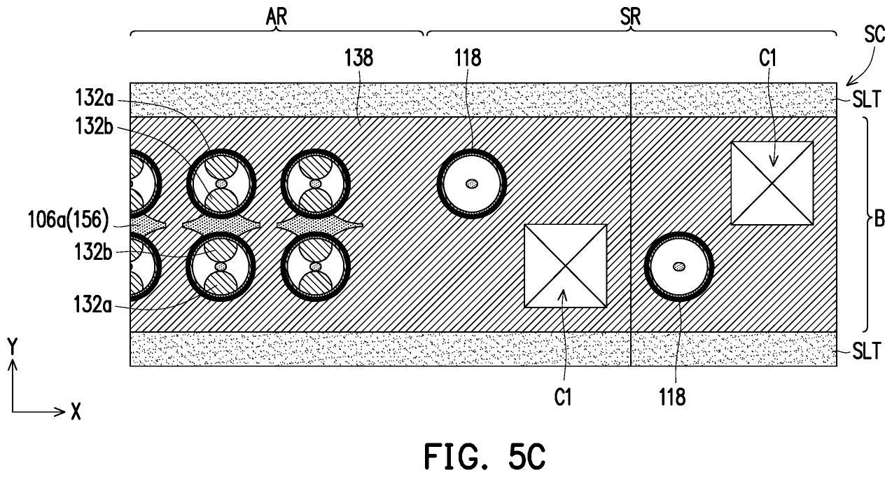

A line connecting the centers of the first conductive pillars 132a and second conductive pillars 132b may be parallel to the Y direction (as shown in FIG. 4A and FIG. 4B), i.e., being perpendicular to the subsequently formed slit SLT (as shown in FIG. 3E), or may form an acute angle with the Y direction (as shown in FIG. 4C and FIG. 4D). In addition, the channel pillars 116 in two adjacent rows may be staggered with each other (as shown in FIG. 3A to FIG. 3E and FIG. 5A) or may be aligned with each other (as shown in FIG. 5B and FIG. 5C). The difference in the radial dimensions of the first and second conductive pillars 132a, the asymmetrical arrangement, and the staggering of the channel pillars 116 in two adjacent rows all conducive to a subsequent routing process.

Afterwards, referring to FIG. 2E to FIG. 2G and FIG. 3B to FIG. 3D, a replacement process is performed to replace the sacrificial layers 106 with a plurality of gate layers 138. First, referring to FIG. 2E and FIG. 3B, a patterning process is performed on the stack structure 102 to form a plurality of slit trenches 133 therein. The slit trenches 133 extend in the X direction, so that the stack structure 102 is divided into a plurality of blocks B.

Next, referring to FIG. 2F, an etching process such as a wet etching process is performed to remove part of the sacrificial layers 106. An etching solution (e.g., hot phosphoric acid) used in the etching process is injected into the slit trenches 133, and then the contacted portion of the sacrificial layers 106 is removed. Therefore, the portion of the sacrificial layers 106 closer to the slit trenches 133 will be removed first, and the portion of the sacrificial layers 106 farther away from the slit trenches 133 will be removed later. In the etching process, during the removal of the sacrificial layers 106 between the channel pillar 116 and the slit trench 133, since the material of the protection layer 110 is different from the material of the sacrificial layer 106, the protection layer 110 may serve as an etch stop layer to protect the charge storage layer 112 around the channel pillar 116.

Referring to FIG. 2G and FIG. 3C, the etching process is continued, and through time mode control, most of the sacrificial layers 106 are removed to form a plurality of horizontal openings 134. In the staircase region SR, the density of the dummy pillars 118 is lower, so the etching rate is higher, and the sacrificial layers 106 are completely etched. In the array region AR, the density of the channel pillars 116 is higher, the flow rate of the etching solution is lower, the etching rate is lower, and the sacrificial layers 106a farthest from the slit trenches 133 are left to form isolation walls 156. The remaining isolation wall 156 covers around the second conductive pillar 132b that is farther away from the slit trench 133. The isolation walls 156 divide the channel pillars 116 in each block B into two rows of channel pillars 116R1 and 116R2, as shown in FIG. 3C. A plurality of second conductive pillars (drain pillars) 136b in the two rows of the channel pillars 116R1 and 116R2 are adjacent to the isolation wall 156, and a plurality of first conductive pillars (source pillars) 136a in the two rows of the channel pillars 116R1 and 116R2 are away from the isolation wall 156.

In addition to time control of the etching, the size of the remaining isolation wall 156 may also be controlled by adjusting the size and density of the dummy pillars 118 in the staircase region SR and the size and density of the channel pillars 116 in the array region AR to control the etching rate of the sacrificial layers 106 in the staircase region SR and the array region AR.

Referring to FIG. 2H and FIG. 3D, the protection layer 110 exposed by the horizontal openings 134 is removed. A part of the protection layer 110, which is adjacent second conductive pillars (drain pillars) 136b, between the sacrificial layers 106a and the charge storage layer 112 is remained. Afterwards, a gate material layer is formed in the slit trenches 133 and the horizontal openings 134. Next, an etch-back process is performed to remove the gate material layer in the slit trenches 133 to form a plurality of gate layers 138 in the horizontal openings 134. In addition, in other embodiments, before the gate layers 138 are formed, a blocking material layer and a barrier material layer are sequentially formed in the slit trench 133 and the horizontal opening 134. The material of the blocking material layer is, for example, a high dielectric constant material having a dielectric constant greater than or equal to 7, such as aluminum oxide (Al₂O₃), hafnium oxide (HfO₂), lanthanum oxide (La₂O₅), transition metal oxide, lanthanide oxide, or combinations thereof. The material of the barrier material layer is, for example, titanium (Ti), titanium nitride (TiN), tantalum (Ta), tantalum nitride (TaN), or a combination thereof. After an etch-back process is performed on the blocking material layer and the barrier material layer, a plurality of blocking layers 136 and a plurality of barrier layers 137 are formed in the horizontal openings 134. The barrier layer 137 is located between the blocking layer 136 and the gate layer 138. The blocking layers 136, the tunneling layer 114, and the charge storage layer 112 are collectively referred to as a charge storage structure 140. At this time, a gate stack structure 150 is formed. The gate stack structure 150 is disposed on the dielectric substrate 100 and includes a plurality of gate layers 138 and a plurality of insulating layers 104 stacked alternately on each other.

In another embodiment, the charge storage layer 112 and the tunneling layer 114 are not formed in the opening 108, but are formed in the gate replacement process. The tunneling layer 114 and the charge storage layer 112 are formed in the horizontal opening 134 before the gate layer 138 is formed. After the charge storage layer 112 is formed, a blocking layer 136, a barrier layer 137, and a gate layer 138 are formed, as shown in FIG. 6.

Referring to FIG. 2I and FIG. 3E, a slit SLT is formed in the slit trench 133. The method of forming the slit SLT includes filling an insulating material on the gate stack structure 150 and in the slit trench 133, and then removing the excessive insulating material on the gate stack structure 150 through an etch-back process or a planarization process. The insulating material is, for example, silicon oxide or silicon nitride.

Afterwards, a contact C1 (as shown in FIG. 3E) is formed in the staircase region SR. The contact C1 lands on the end of the gate layer 138 in the staircase region SR and is electrically connected thereto.

In the embodiments of the disclosure, the isolation wall is buried in the gate layer, so that the gate layer does not cover around the drain pillar, and the gate layer does not overlap with the drain pillar. Therefore, in a de-selected mode, it is possible to significantly reduce or avoid gate induced drain leakage caused by a high reverse bias of the gate and the drain. In the gate replacement process, through time mode control, part of the sacrificial layers can be left to serve as the isolation wall, so it is not necessary to add additional process steps.

What is claimed is:

1. A 3D AND flash memory device comprising:
a gate stack structure located on a dielectric substrate, wherein the gate stack structure comprises a plurality of gate layers and a plurality of insulating layers alternately stacked on each other;
a plurality of channel pillars extending through the gate stack structure;
a plurality of first conductive pillars and a plurality of second conductive pillars, located in the channel pillars and electrically connected to the channel pillars;
a plurality of charge storage structures located between the gate layers and the channel pillar; and
a plurality of isolation walls buried in the gate layers and covering a portion of the charge storage structures at outer sidewalls of the second conductive pillars.

2. The 3D AND flash memory device according to claim 1, wherein each of the charge storage structures and each of the channel pillar has a first chord length and a second chord length, wherein the first chord length is a chord length of an arc surface of the charge storage structure that is in contact with an adjacent isolation wall, the second chord length is a chord length of an arc surface of the channel pillar that is in contact with an adjacent second conductive pillar, and the first chord length is greater than or equal to the second chord length.

3. The 3D AND flash memory device according to claim 1, wherein the isolation walls have a curved profile, extend in a first direction, and divide the channel pillars into first row channel pillars and second row channel pillars.

4. The 3D AND flash memory device according to claim 1, wherein the second conductive pillars (32b) act as drain pillars.

5. The 3D AND flash memory device according to claim 3, wherein the isolation walls extend discontinuously in the first direction.

6. The 3D AND flash memory device according to claim 3, wherein the first row channel pillars and the second row channel pillars are staggered with each other.

7. The 3D AND flash memory device according to claim 3, wherein the first row channel pillars and the second row channel pillars are aligned with each other.

8. The 3D AND flash memory device according to claim 3, further comprising a slit extending through the gate stack structure, wherein the slit extends in the first direction and a length of the slit is greater than a length of the isolation wall.

9. The 3D AND flash memory device according to claim 8, wherein a width of the slit is greater than a width of the isolation wall.

10. The 3D AND flash memory device according to claim 8, wherein the second conductive pillars in the first row channel pillars and the second conductive pillars in the second row channel pillars are adjacent to the isolation walls, and the first conductive pillars in the first row channel pillars and the first conductive pillars in the second row channel pillars are away from the isolation walls.

11. A 3D AND flash memory device comprising:
a gate stack structure located on a dielectric substrate, wherein the gate stack structure comprises a plurality of gate layers and a plurality of insulating layers alternately stacked on each other;
a plurality of channel pillars passing through the gate stack structure;
a plurality of source pillars and a plurality of drain pillars, located in the channel pillars and being in contact with the channel pillars; and
a plurality of charge storage structures located between the gate layers and the channel pillar,
wherein a sidewall of the gate layers is not in contact with a sidewall of a first part of the charge storage structures, and the sidewall of the first part of the charge storage structures covers around the channel pillars that are in contact with the drain pillars.

12. The 3D AND flash memory device according to claim 11, wherein a radial dimension of each of the source pillars is equal to a radial dimension of each of the drain pillars.

13. The 3D AND flash memory device according to claim 11, wherein a radial dimension of each of the source pillars is greater than or equal to a radial dimension of each of the drain pillars.

14. The 3D AND flash memory device according to claim 11, further comprising a slit extending through the gate stack structure, wherein the slit extends in the first direction, the source pillars and the drain pillars are disposed along a second direction, and the second direction is perpendicular to the first direction.

15. The 3D AND flash memory device according to claim 11, wherein the source pillars are disposed to shift with respect to a center of the drain pillars.

16. A method of fabricating a 3D AND flash memory device, comprising:
forming a stack structure on a dielectric substrate, wherein the gate stack structure comprises a plurality of sacrificial layers and a plurality of insulating layers alternately stacked on each other;
forming a plurality of channel pillars extending through the gate stack structure;
forming a plurality of first conductive pillars and a plurality of second conductive pillars, located in the plurality of channel pillars and being in contact with the plurality of channel pillars
partially removing the sacrificial layers to form a plurality of horizontal openings, wherein unremoved portions of the sacrificial layers form a plurality of isolation walls, and the isolation walls have a curved profile;
forming a plurality of gate layers in the horizontal openings; and
forming a plurality of charge storage structures between the gate layers and the channel pillar, wherein the isolation walls cover the charge storage structures at outer sidewalls of the plurality of second conductive pillars.

17. The method of fabricating a 3D AND flash memory device according to claim 16, wherein the isolation walls extend in a first direction and divide the channel pillars into first row channel pillars and second row channel pillars.

18. The method of fabricating a 3D AND flash memory device according to claim 17, wherein the isolation walls extend continuously in the first direction.

19. The method of fabricating a 3D AND flash memory device according to claim 17, wherein the isolation walls extend discontinuously in the first direction.

20. The method of fabricating a 3D AND flash memory device according to claim 16, wherein each of the charge storage structures and each of the channel pillars has a first chord length and a second chord length, wherein the first chord length is a chord length of an arc surface of the charge storage structure that is in contact with an adjacent isolation wall, the second chord length is a chord length of an arc surface of the channel pillar that is in contact with an adjacent drain pillar, and the first chord length is greater than or equal to the second chord length.
